(19) United States
(12) Patent Application Publication
(10) Pub. No.: US 2009/0000550 A1
(43) Pub. Date: Jan. 1, 2009

(54) MANIFOLD ASSEMBLY

(75) Inventors: Toan Q. Tran, San Jose, CA (US); Dimitry Lubormirsky, Cupertino, CA (US); Lun Tsuei, Mountain View, CA (US)

Correspondence Address: MOSER IP LAW GROUP / APPLIED MATERIALS, INC., 1030 BROAD STREET, 2ND FLOOR, SHREWSBURY, NJ, 07702, US

(73) Assignee: APPLIED MATERIALS, INC., Santa Clara, CA (US)

(21) Appl. No.: 11/770,737

(22) Filed: Jun. 29, 2007

(51) Int. Cl. H01L 21/02; F16L 25/00; F17D 1/02; F28F 1/00

(52) U.S. Cl. 118/715; 137/602; 137/798; 165/181

(57) ABSTRACT

Embodiments of a manifold assembly are provided herein. In some embodiments, a manifold assembly includes a first manifold having a first inlet, for coupling to a high temperature fluid source, and a first outlet; a second manifold having a second inlet and a second outlet; and a connector portion coupling the first outlet of the first manifold to the second inlet of the second manifold, the connector portion includes a polymer block; and a thermal isolator disposed between the polymer block and the first manifold.

### BACKGROUND OF THE INVENTION

1. Field of the Invention

The present invention relates to a manifold assembly, and more particularly, to a manifold assembly for conducting the flow of a fluid from a first chamber at a first temperature to a second chamber at a lower temperature.

2. Description of the Related Art

In semiconductor processing, e.g., in the manufacture of integrated circuits, processes often occur that utilize high temperature fluids. For example, high temperature gases may be provided to a process chamber in which a semiconductor or other substrate is disposed for processing (e.g., for deposition, etching, or other processing of material layers disposed on the substrate). In some processes, these high-temperature fluids may be mixed with lower temperature fluids, or may be introduced into temperature controlled processing apparatus to control the temperature of the processing fluids as desired.

For example, some process chambers may include a remote plasma source (RPS) for forming plasma of a process gas remotely from the process chamber into which the dissociated and/or ionized species are to be delivered. Conventionally, the RPS is connected to the processing chamber through a manifold assembly including an RPS manifold and a mixing manifold for mixing the process gas stream provided by the RPS with a dilutant (or carrier) gas or other fluids prior to delivery to the chamber. The RPS manifold is generally coupled to the mixing manifold by a coupling block, often formed from polytetrafluoroethylene (PTFE). Generally, the process gas stream leaving the RPS has a very high temperature, causing the RPS manifold to have a high temperature as well. The mixing manifold may be cooled using water or other coolants to a desired lower temperature. Alternatively or in combination, the fluids with which the process gas stream leaving the RPS is mixed may also have a lower temperature. As such, the coupling block joining the mixing manifold where these fluids converge is often subject to high thermal stresses due to the high temperature process gas stream flowing through the coupling block as well as due to the temperature differential between the RPS manifold and the mixing manifold. The thermal stresses generated in the coupling block may cause deformation, bending, and cracking of the PTFE block, which may lead to failure of the block and leakage of the process gases from the manifold assembly, thereby causing potential safety issues, equipment downtime, and lower yields.

Therefore, a need exists for an improved substrate processing apparatus which addresses one or more of the above problems.

### SUMMARY OF THE INVENTION

Embodiments of a manifold assembly are provided herein. In some embodiments, a manifold assembly includes a first manifold having a first inlet, for coupling to a high temperature fluid source, and a first outlet; a second manifold having a second inlet and a second outlet; and a connector portion coupling the first outlet of the first manifold to the second inlet of the second manifold, the connector portion includes a polymer block; and a thermal isolator disposed between the polymer block and the first manifold.

In some embodiments, a substrate processing apparatus includes a process chamber; a remote plasma source; and a manifold assembly coupling the remote plasma source to the chamber, the manifold assembly includes a first manifold having a first inlet for coupling to the remote plasma source and a first outlet; a second manifold having a second inlet and a second outlet; and a connector portion coupling the first outlet of the first manifold to the second inlet of the second manifold, the connector portion includes a polymer block; and a thermal isolator disposed between the polymer block and the first manifold.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments. In addition, the drawings have been simplified for clarity and are not drawn to scale. Where possible, identical reference numerals have been used to designate elements that are common to the figures.

FIG. 1 depicts a schematic substrate processing apparatus in accordance with some embodiments of the invention; and

FIG. 2 depicts an exploded, partial cut-away view of a manifold assembly in accordance with some embodiments of the invention.

### DETAILED DESCRIPTION

The present invention relates to a manifold assembly for conducting the flow of a fluid from a first chamber to a second chamber, wherein the first chamber is at a first temperature and the second chamber is at second temperature different from the first temperature. In some illustrative embodiments, a manifold assembly provides for the flow of fluids from a Remote Plasma Source (RPS) to a process chamber in a substrate processing apparatus, for example, a chemical vapor deposition (CVD) apparatus, or other apparatus utilizing a remote plasma source.

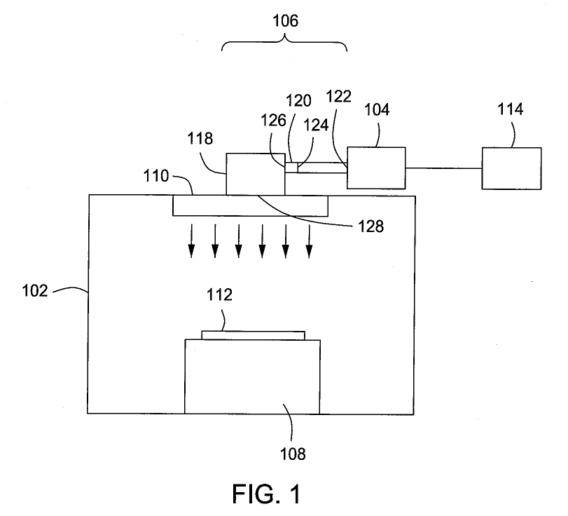

FIG. 1 illustrates a block diagram representing an illustrative substrate processing apparatus 100 in accordance with various embodiments of the present invention. The substrate processing apparatus 100 may be, for example, a chemical vapor deposition (CVD) apparatus, a low pressure, or sub-atmospheric, chemical vapor deposition (LPCVD or SACVD) apparatus, or the like. An example of an SACVD apparatus suitable for use with the invention described herein is the PRODUCERS SACVD processing system available from Applied Materials, Inc., located in Santa Clara, Calif. The substrate processing apparatus 100 generally includes a process chamber 102 and a remote plasma source (RPS) 104 coupled to the process chamber 102 via a manifold assembly 106. The process chamber 102 generally includes a substrate support pedestal 108 for supporting a substrate 112 (such as a semiconductor wafer) thereupon, and a gas inlet, such as a gas distribution plate 110 for providing one or more process gases to the process chamber 102. The RPS 104 may be coupled to one or more gas sources 114 for providing desired process gases or gas mixtures to the process chamber 102 via the manifold assembly 106.

The manifold assembly 106 may include a first manifold 116, a second manifold 118, and a connector portion 120 disposed between the first manifold 116 and the second manifold 118. The first manifold 116 is generally configured for receiving process gases from the RPS 104 and has a first inlet 122 for coupling to the RPS 104 and a first outlet 124. The second manifold 118 is generally configured for receiving the gases from the RPS 104 via the first manifold 116 and has a second inlet 126 and a second outlet 128. The connector portion 120 connects the first outlet 124 to the second inlet 126. The second outlet 128 is coupled to the process chamber 102. Optionally, the second manifold 118 may have additional inlets (not shown) for receiving additional gases, such as carrier gases, dilutant gases, or the like.

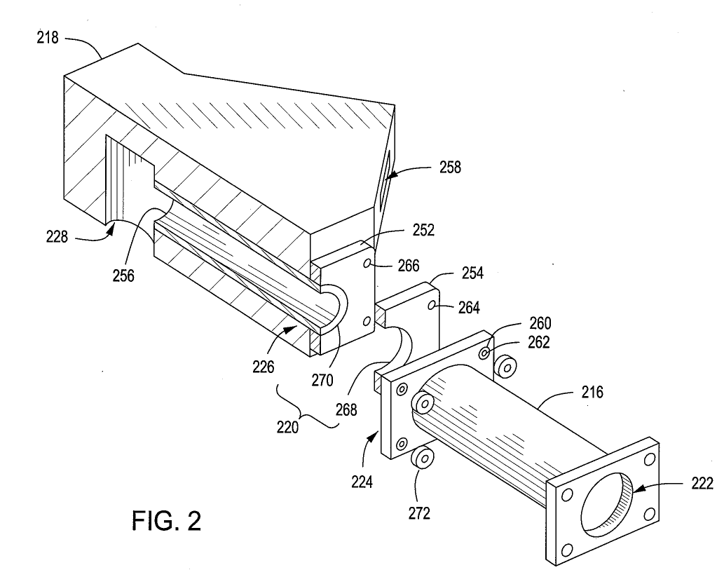

FIG. 2 illustrates a partially cut-away and exploded view of a manifold assembly 206 (similar to the manifold assembly 106 discussed above) in accordance with various embodiments of the present invention. The manifold assembly 206 includes a first manifold 216, a second manifold 218 and a connector portion 220.

The first manifold 116 has a first inlet 222 for coupling to a first fluid source (for example, the RPS 104 described above with respect to FIG. 1) and a first outlet 224. The first manifold 216 may be fabricated of materials suitable for withstanding the processing environment (for example, temperatures, gases, ionized and reactive species formed in the RPS 104, RF compatibility, and the like). In some embodiments, the first manifold 116 may be made of aluminum or alloys thereof.

The second manifold 218 may be fabricated of the same or similar materials as the first manifold 116 and generally includes a second inlet 226 and a second outlet 228. The second manifold 218 may have one or more additional inlets 208 (one inlet 208 shown) for other gases such as carrier gases, dilutant gases, or the like. The second manifold 218 may also include multiple heat transfer fluid distribution channels (not shown) for facilitating control of the temperature of the second manifold 218. For example, the multiple heat transfer fluid distribution may comprise multiple cooling channels to facilitate circulation of a coolant within the second manifold 218 to control the temperature of the second manifold 218 as desired.

The connector portion 220 generally includes a polymer block 252 and a thermal isolator 254. The thermal isolator 254 is disposed between the polymer block 252 and the first manifold 216 and includes a passage 268 to facilitate fluid communication between the first manifold 216 and the second manifold 218. The polymer block 252 is disposed between the thermal isolator 252 and the second manifold 218 and includes a passage 270 to facilitate fluid communication between the first manifold 216 and the second manifold 218. One or more o-rings (not shown) or other sealing mechanisms may be provided between any or all of the polymer block 252 and the second manifold 218, the polymer block 252 and the thermal isolator 254, and the thermal isolator 254 and the first manifold 216 to facilitate maintaining respective seals therebetween.

The thermal isolator 254 may be made of any process compatible materials having a low thermal conductivity, such as ceramics or the like. By way of non-limiting example, the thermal isolator 254 may comprise ceramics, boron carbide, boron nitride, ferrite, silicone carbide, silicone nitride, uranium oxide, and the like, or combinations thereof. In some embodiments, such as when the thermal isolator 254 comprises a ceramic or other RF non-conductive material, the thermal isolator 254 may also provide RF isolation between the first manifold 216 and the second manifold 218.

The polymer block 252 may be fabricated from a high temperature resistant polymer. In some embodiments, the polymer block 252 may be fabricated from polytetrafluoroethylene (PTFE), or similar materials.

Optionally, a sleeve 256 may be disposed within the passage 270 of the polymer block 252. The sleeve 256 may comprise any suitable process compatible material, such as aluminum or the like, that facilitates protecting the polymer block 252 from the processing fluids disposed therein during processing. The sleeve 256 may further reduce the temperature gradient between an inner surface of the polymer block 252 along the passage 270 and exterior surfaces of the polymer block, thereby advantageously reducing the thermal stresses that may develop within the polymer block 252 due to such thermal gradients. In some embodiments, the sleeve 256 may extend at least partially into the second manifold 218. The sleeve 256 and the second manifold 218 may be one machined part or the sleeve 256 may be separately provided.

The first manifold 116, connector portion 120, and the second manifold 118 may be coupled together using any suitable mechanism, such as fasteners, bolts, screws, clamps, or the like. In the embodiment depicted in FIG. 2, a plurality of holes are provided in the manifold 216, thermal isolator 254, polymer block 252, and second manifold 218 (plurality of holes 262, 264, 266 shown) to facilitate bolting the manifold assembly 206 together with a plurality of bolts (not shown), In embodiments where RF power may be present, such as when connected to the RPS 104, an RF isolation insert 260 may be provided to within the holes 262 in the first manifold 216. The insert 260 may be fabricated from materials suitable to provide RF isolation between the bolts or other coupling mechanism passing through the holes 262 and the first manifold 216. In some embodiments, the insert 260 may comprise PTFE, such as Teflon®, or the like.

In some embodiments, such as where RF conductive fasteners are utilized, a plurality of RF isolation washers (one washer 272 shown) may be provided to further facilitate providing RF isolation between the fastener and the first manifold 216. The washers 272 may be fabricated from materials suitable to provide RF isolation between the bolts or other coupling mechanism and the first manifold 216. In some embodiments the RF isolation washers may comprise polyetheretherketone (PEEK), polyimide resin (such as Vespel®), or the like.

In operation, the first inlet 222 of the first manifold 216 may be coupled to a first fluid source (such as the RPS 104 shown in FIG. 1) that provides a first fluid that is to be delivered through the manifold assembly 206 to a process chamber (such as the process chamber 102 shown in FIG. 1). The first fluid travels through the connector portion 220 to the second manifold 218, where the temperature of the first fluid may be adjusted (for example, cooled) by one or more of mixing with additional process fluids (that may have a different temperature than the first fluid) or via thermal conduction between heat transfer fluid flowing in heat transfer fluid distribution channels provided in the second manifold 216.

In some embodiments, the temperature of the first fluid may be very high, such as when the fluid source is an RPS providing a plasma of a desired process gas or gases. For example, in some embodiments, the temperature of the first fluid may be sufficiently high to maintain the first manifold 216 at at temperature of about 250 degrees Celsius. In some embodiments, the temperature of the second manifold 218 may be maintained (for example via a coolant disposed in the heat transfer fluid distribution channels) at a temperature of about 60 degrees Celsius.

When a high temperature gradient exists between the first manifold 216 and the second manifold 218 (such as in the example described above), embodiments of the present invention advantageously provide for more robust coupling of the first manifold 216 and the second manifold 218 in a manner that provides a degree of thermal isolation between the manifolds 216, 218. Specifically, the thermal isolator 254 advantageously restricts heat conduction from the first manifold 216 to the polymer block 252 of the connector portion 220, thereby reducing the lateral thermal gradient between the polymer block 252 and the second manifold 218, and thereby reducing the risk of leakage or failure due to thermally induced fractures of the polymer block 252. In some embodiments, the sleeve 256 further advantageously reduces the radial thermal gradient between the inner surface of the polymer block 252 along the passage 270 and the outer surfaces of the block, thereby further reducing the risk of leakage or failure due to thermally induced fractures of the polymer block 252.

Thus, embodiments of a manifold assembly for conducting the flow of a fluid from a first chamber to a second chamber have been provided herein. In some embodiments, the manifold assembly may provide for various advantages such as reduced leakage and/or failure due to thermally induced fractures. Furthermore, processing systems incorporating the manifold assembly have been described herein. Moreover, the manifold assembly may be retrofitted into existing processing systems.

While the foregoing is directed to some embodiments of the present invention, other and further embodiments of the invention may be devised without departing from the basic scope thereof, and the scope thereof is determined by the claims that follow.

What is claimed is:

1. A manifold assembly, comprising:
a first manifold having a first inlet, for coupling to a high temperature fluid source, and a first outlet;
a second manifold having a second inlet and a second outlet; and
a connector portion coupling the first outlet of the first manifold to the second inlet of the second manifold, the connector portion comprising:
a polymer block; and
a thermal isolator disposed between the polymer block and the first manifold.

2. The manifold assembly of claim 1, wherein the polymer block comprises polytetrafluoroethylene (PTFE).

3. The manifold assembly of claim 1, wherein the thermal isolator comprises ceramic.

4. The manifold assembly of claim 1, wherein the high temperature fluid source is a remote plasma source.

5. The manifold assembly of claim 1, wherein second manifold further comprises a plurality of cooling channels formed therein.

6. The manifold assembly of claim 1, wherein second manifold further comprises a second inlet for coupling to a second fluid source.

7. The manifold assembly of claim 1, wherein first manifold comprises aluminum.

8. The manifold assembly of claim 1, wherein second manifold comprises aluminum.

9. The manifold assembly of claim 1, further comprising:
a tube disposed within the polymer block.

10. The manifold assembly of claim 9, wherein the tube comprises aluminum.

11. The manifold assembly of claim 9, wherein the tube extends into the second manifold.

12. A substrate processing apparatus, comprising:
a process chamber;
a remote plasma source; and
a manifold assembly coupling the remote plasma source to the chamber, the manifold assembly comprising:
a first manifold having a first inlet, for coupling to the remote plasma source, and a first outlet;
a second manifold having a second inlet and a second outlet; and
a connector portion coupling the first outlet of the first manifold to the second inlet of the second manifold, the connector portion comprising:
a polymer block; and
a thermal isolator disposed between the polymer block and the first manifold.

13. The substrate processing apparatus of claim 12, wherein the polymer block comprises polytetrafluoroethylene (PTFE).

14. The substrate processing apparatus of claim 12, wherein the thermal isolator comprises ceramic.

15. The substrate processing apparatus of claim 12, wherein second manifold further comprises a plurality of cooling channels formed therein.

16. The substrate processing apparatus of claim 12, wherein second manifold further comprises a second inlet for coupling to a second fluid source.

17. The substrate processing apparatus of claim 12, wherein first manifold comprises aluminum.

18. The substrate processing apparatus of claim 12, wherein second manifold comprises aluminum.

19. The substrate processing apparatus of claim 12 further comprising a tube disposed within the polymer block.

20. The substrate processing apparatus of claim 19, wherein the tube comprises aluminum.

21. The substrate processing apparatus of claim 19, wherein the tube extends into the second manifold.
